(19) United States
(12) Patent Application Publication
(10) Pub. No.: US 2007/0291452 A1
(43) Pub. Date: Dec. 20, 2007

(54) Heat Transfer Systems for Dissipating Thermal Loads From a Computer Rack

(76) Inventors: Don A. Gilliland, Rochester, MN (US); Cary M. Huettner, Rochester, MN (US)

Correspondence Address: IBM (ROC-BLF), C/O BIGGERS & OHANIAN, LLP, P.O. BOX 1469, AUSTIN, TX, 78767-1469, US

(21) Appl. No.: 11/424,045

(22) Filed: Jun. 14, 2006

(51) Int. Cl. H05K 7/20

(52) U.S. Cl. 361/699

(57) ABSTRACT

Heat transfer systems for dissipating thermal loads from a computer rack are disclosed that include: an expandable heat transfer bus extending along the rack, the expandable heat transfer bus capable of passing a thermal transport; one or more heat sinks connected to the expandable heat transfer bus, each heat sink capable of receiving the thermal transport from the bus and returning the thermal transport to the bus, and each heat sink capable of transferring into the thermal transport a thermal load from an electronic component inside a rack module mounted to the rack; and a heat exchanger connected to the expandable heat transfer bus capable of dissipating the thermal load of the thermal transport.

### BACKGROUND OF THE INVENTION

1. Field of the Invention

The field of the invention is heat transfer systems for dissipating thermal loads from a computer rack, expandable heat transfer buses for dissipating thermal loads from a computer rack, and methods for configuring the dissipation of thermal loads from heat sinks in a computer rack.

2. Description of Related Art

The development of the EDVAC computer system of 1948 is often cited as the beginning of the computer era. Since that time, users have relied on computer systems to simplify the process of information management. Today's computer systems are much more sophisticated than early systems such as the EDVAC. Such modem computer systems deliver powerful computing resources to provide a wide range of information management capabilities through the use of computer software such as database management systems, word processors, spreadsheets, client/server applications, web services, and so on.

In order to deliver powerful computing resources, computer architects must design powerful computer processors and high-speed memory modules. For example, current computer processors are capable of executing billions of computer program instructions per second, and memory module are capable of transferring up to 1.6 Gigabits of data per second. Operating these computer processors and memory modules requires a significant amount of power. Often processors can consume over 100 watts during operation. Consuming significant amounts of power generates a considerable amount of heat. Unless the heat is removed, the heat generated by a computer processor or memory module may degrade or destroy the component's functionality.

To prevent the degradation or destruction of an electronic component, a computer architect may remove heat from the electronic component by using traditional heat sinks or liquid cooling technologies. Traditional heat sinks have fins for dissipating heat into the environment surrounding the heat sink. Traditional heat sinks absorb the heat from an electronic component and transfer the heat to the heat-dissipating fins by conduction. The drawback of traditional heat sinks is that such heat sinks typically require large amounts of physical space and increase the temperature of the environment surrounding the heat sink. Consider, for example, a typical computer room having multiple computer racks. Each rack having multiple rack mounted blade server chassis, and each blade server chassis containing thirty-two computer processors. There is often not enough physical space inside the blade server chassis to install a traditional heat sink of adequate size to cool the processors or memory modules. Even if the physical space does exist to install some heat sinks, the heat dissipated by the heat sinks typically raises the temperature in the computer room significantly. Such an increase in the temperature in the environment surrounding the heat sinks reduces the heat sinks' ability to dissipate the thermal load. Often a costly, second cooling solution is required to reduce the temperature in the computer room to an acceptable level.

Liquid cooling technologies typically pass a thermally conductive liquid through a finless heat sink, often referred to as a ‘cold plate.’ The cold plate is adjacent to an electronic component and absorbs the heat generated by the component. After absorbing the heat, liquid cooling solutions quickly transfer the liquid away to a heat exchanger such as, for example, a traditional heat sink to cool the liquid. Transferring the liquid away from the electronic component quickly removes the heat from the location of the component. The cooled liquid is then returned to the processor or memory module to start the cycle again. The drawback to current liquid cooling technologies is that such technologies typically utilize a liquid cooler a few centimeters away from the electronic component that takes up as much physical space as a traditional heat sink—often because liquid cooler utilizes a traditional heat sink. For computing environments such as in the example above that have multiple computer racks with multiple components requiring cooling, some current liquid cooling technologies utilize a large liquid cooler that stands alone in the computer room and connects to all the components through hoses that extend along the floor. The drawback to such solutions is that these solutions are costly, cumbersome, and typically do nothing to reduce the heat released into the computer room.

### SUMMARY OF THE INVENTION

Heat transfer systems for dissipating thermal loads from a computer rack are disclosed that include: an expandable heat transfer bus extending along the rack, the expandable heat transfer bus capable of passing a thermal transport; one or more heat sinks connected to the expandable heat transfer bus, each heat sink capable of receiving the thermal transport from the bus and returning the thermal transport to the bus, and each heat sink capable of transferring into the thermal transport a thermal load from an electronic component inside a rack module mounted to the rack; and a heat exchanger connected to the expandable heat transfer bus capable of dissipating the thermal load of the thermal transport.

Expandable heat transfer buses for dissipating thermal loads from a computer rack are disclosed that include: a hot bus pipe capable of connecting to one or more heat sinks, receiving a thermal transport carrying the thermal loads of heat sinks from electronic components inside rack modules mounted on the rack, and passing the thermal transport to a heat exchanger capable of cooling the thermal transport; a cold bus pipe capable of connecting to the heat sinks and returning to the heat sinks the cooled thermal transport from a heat exchanger; and a heat exchanger connected to the hot bus pipe and the cold bus pipe and capable of cooling the thermal transport.

Method for configuring the dissipation of thermal loads from heat sinks in a computer rack are disclosed that include: quick connecting a heat sink to an expandable hot bus pipe capable of receiving a thermal transport carrying the thermal load of the heat sink from electronic component inside a rack module mounted on the rack and capable of passing the thermal transport to a heat exchanger capable of cooling the thermal transport; and quick connecting the heat sink to an expandable cold bus pipe capable of returning to the heat sink the cooled thermal transport from the heat exchanger.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth a perspective view of an exemplary heat transfer system for dissipating thermal loads from a computer rack according to embodiments of the present invention.

FIG. 2 sets forth a perspective view of an exemplary heat exchanger useful in a heat transfer system for dissipating thermal loads from a computer rack according to embodiments of the present invention.

FIG. 3 sets forth a view of cross-section ‘3’ in the exemplary heat exchanger of FIG. 2.

FIG. 4 sets forth a flow chart illustrating an exemplary method for configuring the dissipation of thermal loads from heat sinks in a computer rack according to embodiments of the present invention.

FIG. 5 sets forth a flow chart illustrating a further exemplary method for configuring the dissipation of thermal loads from heat sinks in a computer rack according to embodiments of the present invention.

### DETAILED DESCRIPTION OF EXEMPLARY EMBODIMENTS

### Detailed Description

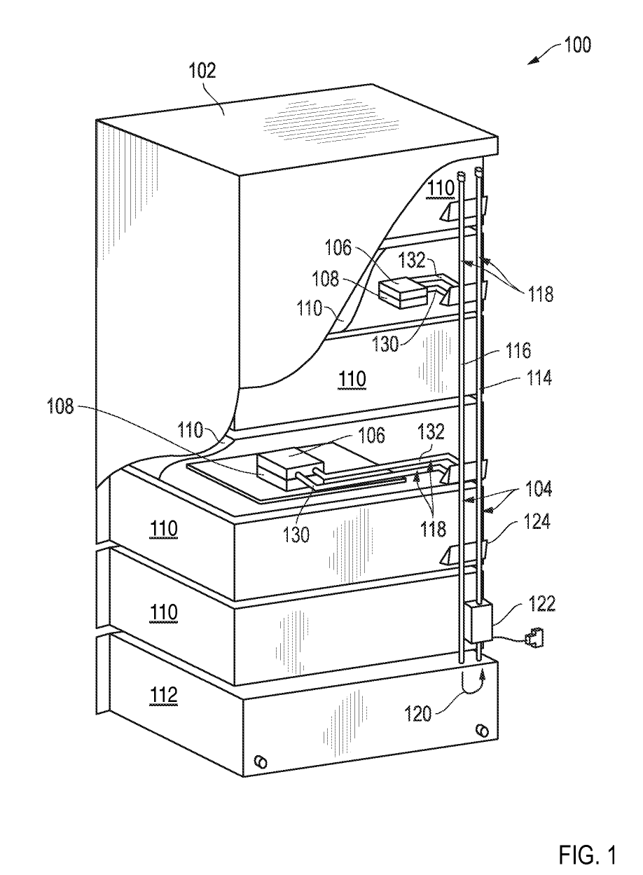

Exemplary heat transfer systems for dissipating thermal loads from a computer rack, expandable heat transfer buses for dissipating thermal loads from a computer rack, and methods for configuring the dissipation of thermal loads from heat sinks in a computer rack according to embodiments of the present invention are described with reference to the accompanying drawings, beginning with FIG. 1. FIG. 1 sets forth a perspective view of an exemplary heat transfer system (100) for dissipating thermal loads from a computer rack (102) according to embodiments of the present invention. A thermal load is the thermal energy generated by an electronic component (108) such as, for example, a computer processor or memory module. A measure of thermal load is typically expressed in units of Joules. The rate at which an electronic component (108) produces a thermal load over time is typically expressed in units of Watts.

The computer rack (102) illustrated in FIG. 1 is a standardized frame, typically 19 inches wide, for mounting various electronic rack modules (110) in a ‘stack.’ Equipment designed to be placed in a rack is typically described as rack-mounted, a rack-mounted system, having a rack mount chassis, or a shelf. The rack modules (110) mounted to the rack (102) of FIG. 1 are rack-mounted chassis containing electronic components (108) generating thermal loads. Examples of a rack module (110) may include a blade server chassis, rack-mounted power management module, rack-mounted storage array, and so on.

In the example of FIG. 1, each electronic component (108) generating a thermal load thermally connects to a heat sink (106) such as, for example a cold plate. A heat sink (106) is a thermal conductor configured to absorb and dissipate the thermal load from the electronic component (108) thermally connected with the heat sink (106). Thermal conductors used in designing the heat sink (106) may include, for example, aluminum, copper, silver, aluminum silicon carbide, or carbon-based composites. Heat sink (106) absorbs the thermal load from the electronic component by thermal conduction. When thermally connected to an electronic component (108), the heat sink provides additional thermal mass, cooler than the electronic component (108), into which the thermal load may flow. After absorbing the thermal load, each heat sink (106) of FIG. 1 transfers into a thermal transport (118) a thermal load from an electronic component (108) inside a rack module (110) mounted to the rack (102). The thermal transport (118) carries the thermal load away from the heat sink (106) and the electronic component (108). The thermal transport (118) is a thermally conductive fluid such as, for example, liquid metal or the family of perfluorinated liquids developed by 3M™ generally referred to as Fluorinert™.

The exemplary heat transfer system (100) of FIG. 1 includes an expandable heat transfer bus (104) extending along the rack (102). The expandable heat transfer bus (104) is a thermal bus that provides a common heat exchanger for dissipating thermal loads to a plurality of heat sinks (106) in the computer rack (102). In the example of FIG. 1, the expandable heat transfer bus (104) is capable of passing a thermal transport (118) between a heat exchanger and the plurality of heat sinks (106) connected to components (108) generating thermal loads. To facilitate access to the bus (104), the exemplary expandable heat transfer bus (104) of FIG. 1 includes a dripless quick connector (124) capable of connecting each heat sink to the expandable heat transfer bus. The expandable heat transfer bus (104) is ‘expandable’ because once the bus (104) is installed in the rack (102), cooling may be provided to any number of components (108) in the rack modules (110) of the rack (102) by simply connecting a heat sink (106) to the component (108) and connecting the heat sink (106) to the heat transfer bus (104).

The exemplary expandable heat transfer bus (104) of FIG. 1 includes a hot bus pipe (114) capable of connecting to one or more heat sinks (106). In the example of FIG. 1, the hot bus pipe (114) is a pipe capable of receiving the thermal transport (118) carrying the thermal load of the heat sinks (106) from the electronic components (108) and passing the thermal transport (118) to a heat exchanger capable of cooling the thermal transport (118). To facilitate access to the hot bus pipe (114), the exemplary expandable heat transfer bus (104) of FIG. 1 includes a dripless quick connector (124) capable of connecting each heat sink to the hot bus pipe (114). In the example of FIG. 1, the hot bus pipe (114) is capped off at the upper end to force the thermal transport (118) into the heat sinks (106). The lower end of the hot bus pipe (114) extends into a heat exchanger capable of cooling the thermal transport (118).

The exemplary expandable heat transfer bus (104) of FIG. 1 also includes a cold bus pipe (116) capable of connecting to one or more heat sinks (106). In the example of FIG. 1, the cold bus pipe (116) is a pipe capable of returning to the heat sinks (106) the cooled thermal transport from a heat exchanger. To facilitate access to the cold bus pipe (116), the exemplary expandable heat transfer bus (104) of FIG. 1 includes a dripless quick connector (124) capable of connecting each heat sink to the cold bus pipe (116). In the example of FIG. 1, the cold bus pipe (116) is capped off at the upper end to extract the thermal transport (118) out the heat sinks (106). The lower end of the cold bus pipe (116) extends into a heat exchanger capable of providing the cooled thermal transport (118).

As mentioned above, the exemplary heat transfer system (100) of FIG. 1 includes one or more heat sinks (106) connected to the expandable heat transfer bus (104). Each heat sink (106) is capable of receiving the thermal transport (118) from the bus (104) and returning the thermal transport (118) to the bus (104). In the example of FIG. 1, each heat sink (106) receives the thermal transport (118) from the cold bus pipe (116) through a cold pipe stub (130). The cold pipe stub (130) is a pipe that connects to a heat sink (106) and quick connects to the cold bus pipe (116) of the expandable heat transfer bus (104). The cold pipe stub (130) is capable of carrying a thermal transport to the cold bus pipe (116) of the expandable heat transfer bus (104) to a heat sink (106). In the example of FIG. 1, each heat sink (106) returns the thermal transport (118) to the hot bus pipe (114) through a hot pipe stub (132). The hot pipe stub (132) is a pipe that connects to a heat sink (106) and quick connects to the hot bus pipe (114) of the expandable heat transfer bus (104). The hot pipe stub (132) is capable of carrying a thermal transport from a heat sink (106) to the hot bus pipe (406) of the expandable heat transfer bus (104).

The exemplary heat transfer system (100) of FIG. 1 includes a heat exchanger (112) connected to the expandable heat transfer bus (104). The heat transfer bus (104) in the example of FIG. 1 mounts on the heat exchanger (112). The heat exchanger (112) of FIG. 1 is capable of dissipating the thermal load of the thermal transport (118). The heat exchanger (112) of FIG. 1 connects to the hot bus pipe (114) to receive the thermal transport carrying thermal loads, cools the thermal transport (118) by dissipating the thermal load, and connects to the cold bus pipe (116) to provide the cooled thermal transport to heat sinks (106) connected to the bus (104). In the example of FIG. 1, the heat exchanger (112) is a standard size capable of mounting in the rack (102) and mounts on the rack (102) below the rack modules (110). Mounting the heat exchanger (112) of FIG. 1 in the computer rack (102) advantageously allows for a heat transfer system for dissipating thermal loads using a standard 19 inch computer rack modified according to embodiments of the present invention.

In the example of FIG. 1, the hot bus pipe (114) and the cold bus pipe (116) are configured to form a loop (120). The loop (120) is formed by the hot bus pipe (114), the cold bus pipe (116), a portion of the thermal bus (104) enclosed in a heat exchanger (112), and the pipe stubs (130, 132). The expandable heat transfer bus (104) of FIG. 1 includes a bus pump (122) capable of circulating the thermal transport (118) through the loop (120). The bus pump (122) includes a power connector capable of receiving power from the power bus (not shown) of the computer rack (102). In the example of FIG. 1, the thermal transport is implemented as liquid metal and the bus pump is implemented as an electromagnetic pump for circulating the liquid metal.

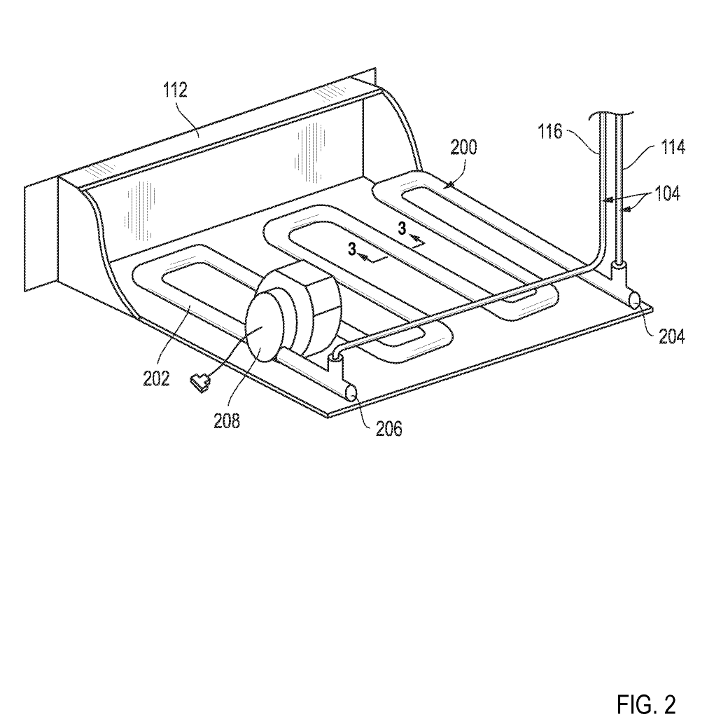

As mentioned above, the exemplary heat transfer system of FIG. 1 includes a heat exchanger for dissipating the thermal load of the thermal transport. For further explanation, therefore, FIG. 2 sets forth a perspective view of an exemplary heat exchanger (112) useful in a heat transfer system for dissipating thermal loads from a computer rack according to embodiments of the present invention. The exemplary heat exchanger (112) of FIG. 2 includes a heat-dissipating thermal transport (200). A heat-dissipating thermal transport (200) is a thermally conductive fluid that dissipates the thermal loads away from a computer rack that were generated by electrical components inside the computer rack. In the example of FIG. 2, the heat-dissipating thermal transport is implemented as water.

The exemplary heat exchanger (112) of FIG. 2 also includes an exchanger pipe (202). The exchanger pipe (202) is a pipe through which the heat-dissipating thermal transport passes. The exchanger pipe (202) has an exchanger inlet (204) capable of receiving the heat-dissipating thermal transport (200) from a building facilities provider. The exchanger pipe (202) also has an exchanger outlet (206) capable of returning the heat-dissipating thermal transport (200) to the building facilities provider. In the example of FIG. 2, the building facilities provider is implemented as the water provider that supplies water for the building containing the computer rack. To move the heat-dissipating thermal transport (200) through the exchanger pipe, the heat exchanger (112) also includes an exchanger pump (208) capable of circulating the heat-dissipating thermal transport (200) through the exchanger pipe (202). The exchanger pump (208) includes a power connector capable of receiving power from a power bus of the computer rack.

In the example of FIG. 2, the heat exchanger (112) encloses a portion of the expandable heat transfer bus (104). Enclosing a portion of the expandable heat transfer bus (104) in the heat exchanger (112) allows the heat exchanger (112) of FIG. 2 to receive from the hot bus pipe (114) the thermal transport (118), transfer the thermal loads from the thermal transport (118) into the heat-dissipating thermal transport (200), and return the thermal transport to the cold bus pipe (116). Readers will note that transferring the thermal loads into the heat-dissipating thermal transport (200) and returning the heat-dissipating thermal transport (200) to the building facilities provider removes the thermal loads from the building containing the computer rack. Removing the thermal loads from the building advantageously allows for a heat transfer system for dissipating thermal loads according to embodiments of the present invention that does not significantly increase the temperature of the room containing the computer rack.

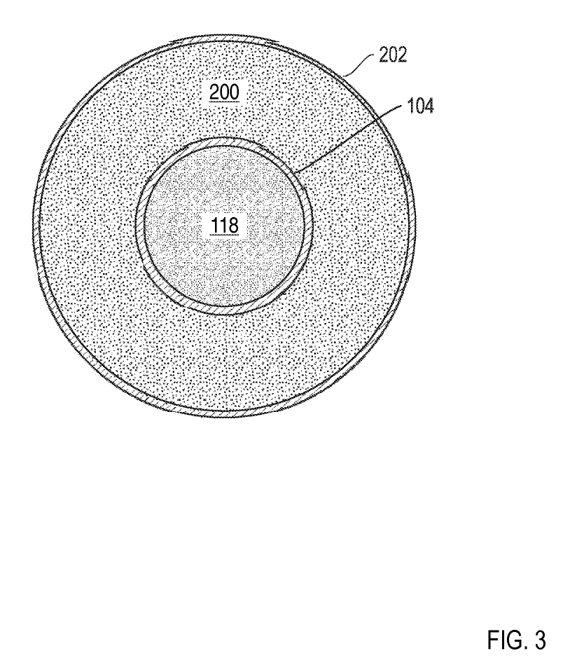

As mentioned above, the heat exchanger may enclose a portion of the expandable heat transfer bus. For further explanation, therefore, FIG. 3 sets forth a view of cross-section ‘3’ in the exemplary heat exchanger of FIG. 2 that illustrates a portion of the expandable heat transfer bus (104) enclosed in the exchanger pipe (202). In the example of FIG. 3, the thermal transport (118) passes through the expandable heat transfer bus (104). Similarly, the heat-dissipating thermal transport (200) passes through the exchanger pipe (202) and surrounds the expandable heat transfer bus (104) and the thermal transport (118) in the heat exchanger. The thermal transport of FIG. 3 is implemented as liquid metal, and the heat-dissipating thermal transport of FIG. 3 is implemented as water from the building facilities provider.

Enclosing a portion of the expandable heat transfer bus (104) in the exchanger pipe (202) allows the heat exchanger to transfer the thermal loads carried by the thermal transport (118) into the heat-dissipating thermal transport (200). As the thermal transport (118) passes through the cooler heat-dissipating thermal transport (200), the thermal load flows from the thermal transport (118) into the heat-dissipating thermal transport (200). Transferring the thermal load from the thermal transport (118) into the heat-dissipating thermal transport (200) cools the thermal transport (118) and warms the heat-dissipating thermal transport (200). The cooled thermal transport (118) is returned to the heats sinks connected to the expandable heat transfer bus (104), while the warmed heat-dissipating thermal transport is returned to the building facilities provider.

Readers will note that FIG. 3 depicts the cross section of the expandable heat transfer bus (104) and the exchanger pipe (202) as circular in shape. Such a depiction is for explanation and not for limitation. In fact, shape of the cross section of the expandable heat transfer bus (104) and the exchanger pipe (202) may any shape as will occur to those of skill in the art. Factors that may affect the shape of the cross section of the expandable heat transfer bus (104) and the exchanger pipe (202) may include a shape's efficiency at transferring the thermal load from the thermal transport (118) to the heat-dissipating thermal transport (200), the manufacturing limitations for a particular shape, the type of material used to construct the expandable heat transfer bus (104) and the exchanger pipe (202), and so on.

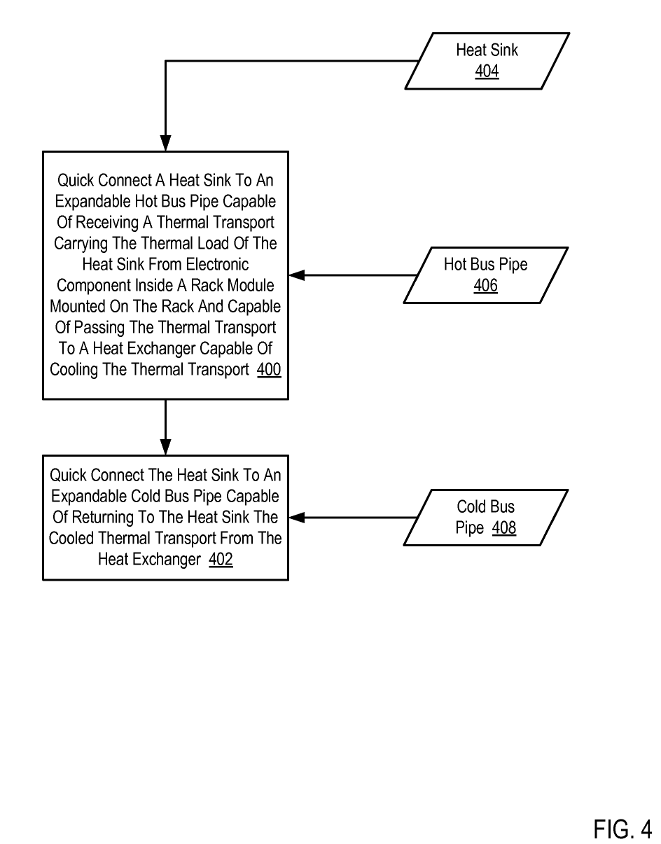

As mentioned above, methods for configuring the dissipation of thermal loads from heat sinks in a computer rack according to embodiments of the present invention are described with reference to the accompanying drawings. For further explanation, therefore, FIG. 4 sets forth a flow chart illustrating an exemplary method for configuring the dissipation of thermal loads from heat sinks in a computer rack according to embodiments of the present invention.

The method of FIG. 4 includes quick connecting (400) a heat sink (404) to an expandable hot bus pipe (406). The heat sink (404) is thermal conductor configured to absorb and dissipate the thermal load from an electronic component using a thermal transport. As mentioned above, a thermal transport is a thermally conductive fluid such as, for example, liquid metal or the family of perfluorinated liquids developed by 3M™ generally referred to as Fluorinert™. Quick connecting (400) a heat sink (404) to an expandable hot bus pipe (406) according to the method of FIG. 4 may be carried out by connecting a hot pipe stub to the heat sink and quick connecting the hot pipe stub to the hot bus pipe (406). A hot pipe stub is a pipe capable of carrying a thermal transport from the heat sink (404) to the hot bus pipe (406) of the expandable heat transfer bus.

The hot bus pipe (406) of FIG. 4 is a pipe capable of receiving a thermal transport carrying the thermal load of the heat sink from electronic component inside a rack module mounted on the rack and capable of passing the thermal transport to a heat exchanger capable of cooling the thermal transport. An example of a hot bus pipe useful in configuring the dissipation of thermal loads from heat sinks in a computer rack according to embodiments of the present invention may include the hot bus pipe describe above with reference to FIG. 1.

The method of FIG. 4 also includes quick connecting (402) the heat sink (404) to an expandable cold bus pipe (408). The cold bus pipe (408) is a pipe capable of returning to the heat sink the cooled thermal transport from a heat exchanger. An example of a cold bus pipe useful in configuring the dissipation of thermal loads from heat sinks in a computer rack according to embodiments of the present invention may include the cold bus pipe describe above with reference to FIG. 1. Quick connecting (402) the heat sink (404) to an expandable cold bus pipe (408) according to the method of FIG. 4 may be carried out by connecting a cold pipe stub to the heat sink and quick connecting the cold pipe stub to the cold bus pipe (404). A cold pipe stub is a pipe capable of carrying a thermal transport from the cold bus pipe (404) of the expandable heat transfer bus to the heat sink (404).

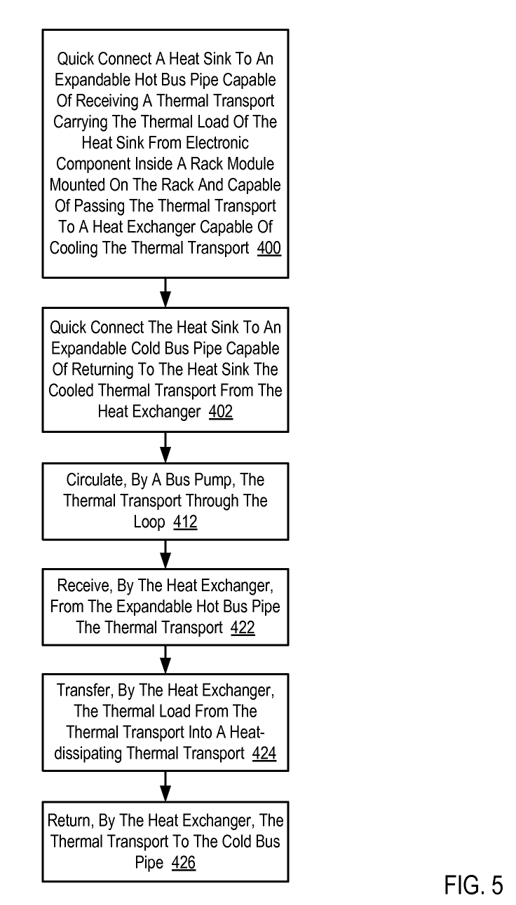

As mentioned above, the hot bus pipe and the cold bus pipe may be configured to form a loop through which the thermal transport may be circulated. For further explanation, therefore, FIG. 5 sets forth a flow chart illustrating a further exemplary method for configuring the dissipation of thermal loads from heat sinks in a computer rack according to embodiments of the present invention in which the hot bus pipe and the cold bus pipe are configured to form a loop and that includes circulating (412), by a bus pump, the thermal transport through the loop.

The method of FIG. 5 is similar to the method of FIG. 4. That is, the method of FIG. 5 is similar to the method of FIG. 4 in that the method of FIG. 5 includes quick connecting (400) a heat sink to an expandable hot bus pipe. The expandable hot bus pipe is capable of receiving a thermal transport carrying the thermal load of the heat sink from electronic component inside a rack module mounted on the rack and capable of passing the thermal transport to a heat exchanger capable of cooling the thermal transport. The method of FIG. 5 is also similar to the method of FIG. 4 in that the method of FIG. 5 includes quick connecting (402) the heat sink to an expandable cold bus pipe. The cold bus pipe is capable of returning to the heat sink the cooled thermal transport from the heat exchanger. The example of FIG. 5 is also similar to the example of FIG. 4 in that the example of FIG. 5 includes a heat sink.

The method of FIG. 5 differs from the method of FIG. 4 in that the method of FIG. 5 includes circulating (412), by a bus pump, the thermal transport through the loop. As mentioned above, the thermal transport is a thermally conductive fluid such as, for example, liquid metal or the family of perfluorinated liquids developed by 3M™ generally referred to as Fluorinert™.

The method of FIG. 5 also includes receiving (422), by the heat exchanger, from the expandable hot bus pipe the thermal transport, transferring (424), by the heat exchanger, the thermal load from the thermal transport into a heat-dissipating thermal transport, and returning (426), by the heat exchanger, the thermal transport to the cold bus pipe. Receiving (422) from the expandable hot bus pipe the thermal transport, transferring (424) the thermal load from the thermal transport into a heat-dissipating thermal transport, and returning (426) the thermal transport to the cold bus pipe may be carried out by enclosing a portion of the hot bus pipe and the cold bus pipe in an exchanger pipe capable of passing a heat-dissipating thermal transport. The heat-dissipating thermal transport is a thermally conductive fluid that dissipates the thermal loads away from a computer rack that were generated by electrical components inside the computer rack. The exchanger pipe is a pipe through which the heat-dissipating thermal transport passes.

As mentioned above, enclosing a portion of the hot bus pipe and the cold bus pipe in an exchanger pipe allows the heat exchanger to transfer the thermal loads carried by the thermal transport into the heat-dissipating thermal transport. As the thermal transport passes through the cooler heat-dissipating thermal transport, the thermal load flows from the thermal transport into the heat-dissipating thermal transport. Transferring the thermal load from the thermal transport into the heat-dissipating thermal transport cools the thermal transport and warms the heat-dissipating thermal transport. The cooled thermal transport is returned to the heats sink connected to the hot bus pipe and the cold bus pipe.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A heat transfer system for dissipating thermal loads from a computer rack, the heat transfer system comprising:
an expandable heat transfer bus extending along the rack, the expandable heat transfer bus capable of passing a thermal transport;
one or more heat sinks connected to the expandable heat transfer bus,
each heat sink capable of receiving the thermal transport from the bus and returning the thermal transport to the bus, and
each heat sink capable of transferring into the thermal transport a thermal load from an electronic component inside a rack module mounted to the rack; and
a heat exchanger connected to the expandable heat transfer bus capable of dissipating the thermal load of the thermal transport.

2. The heat transfer system of claim 1 wherein the expandable heat transfer bus further comprises:
a hot bus pipe capable of receiving the thermal transport carrying the thermal load of the heat sinks from the electronic components and passing the thermal transport to the heat exchanger capable of cooling the thermal transport; and
a cold bus pipe capable of returning to the heat sinks the cooled thermal transport from the heat exchanger.

3. The heat transfer system of claim 2 wherein:
the hot bus pipe and the cold bus pipe are configured to form a loop; and
the expandable heat transfer bus further comprises a bus pump capable of circulating the thermal transport through the loop.

4. The heat transfer system of claim 3 wherein:
the thermal transport is liquid metal; and
the bus pump is an electromagnetic pump.

5. The heat transfer system of claim 1 wherein the expandable heat transfer bus further comprises a dripless quick connector capable of connecting each heat sink to the expandable heat transfer bus.

6. The heat transfer system of claim 1 wherein:
the heat exchanger is a standard size capable of mounting in the rack and mounts on the rack below the rack modules; and
the expandable heat transfer bus mounts on the heat exchanger.

7. The heat transfer system of claim 1 wherein the heat exchanger further comprises:
a heat-dissipating thermal transport;
an exchanger pipe, the exchanger pipe having an exchanger inlet capable of receiving the heat-dissipating thermal transport from a building facilities provider and having an exchanger outlet capable of returning the heat-dissipating thermal transport to the building facilities provider; and
a exchanger pump capable of circulating the heat-dissipating thermal transport through the exchanger pipe.

8. The heat transfer system of claim 1 wherein the heat exchanger encloses a portion of the expandable heat transfer bus.

9. The heat transfer system of claim 1 wherein:
the heat exchanger encloses a portion of the expandable heat transfer bus; and
the heat-dissipating thermal transport surrounds the thermal transport in the heat exchanger.

10. The heat transfer system of claim 1 wherein the heat-dissipating thermal transport is water.

11. A expandable heat transfer bus for dissipating thermal loads from a computer rack, the heat transfer bus comprising:
a hot bus pipe capable of connecting to one or more heat sinks, receiving a thermal transport carrying the thermal loads of heat sinks from electronic components inside rack modules mounted on the rack, and passing the thermal transport to a heat exchanger capable of cooling the thermal transport;
a cold bus pipe capable of connecting to the heat sinks and returning to the heat sinks the cooled thermal transport from a heat exchanger; and
a heat exchanger connected to the hot bus pipe and the cold bus pipe and capable of cooling the thermal transport.

12. The expandable heat transfer bus of claim 11 wherein the hot bus pipe and the cold bus pipe are configured to form a loop, the expandable heat transfer bus further comprising:
a bus pump capable of circulating the thermal transport through the loop.

13. The expandable heat transfer bus of claim 12 wherein:
the thermal transport is liquid metal; and
the bus pump is an electromagnetic pump.

14. The expandable heat transfer bus of claim 11 further comprising a dripless quick connector capable of connecting each heat sink to the hot bus pipe.

15. The expandable heat transfer bus of claim 11 further comprising a dripless quick connector capable of connecting each heat sink to the cold bus pipe.

16. The expandable heat transfer bus of claim 11 wherein the heat exchanger further comprises:
a heat-dissipating thermal transport; and
an exchanger pipe capable of:
receiving from the hot bus pipe the thermal transport,
transferring the thermal loads from the thermal transport into a heat-dissipating thermal transport, and
returning the thermal transport to the cold bus pipe.

17. The expandable heat transfer bus of claim 16 wherein:
the exchanger pipe further comprises an exchanger inlet capable of receiving the heat-dissipating thermal transport from a building facilities provider and an exchanger outlet capable of returning the heat-dissipating thermal transport to the building facilities provider; and
a exchanger pump capable of circulating the heat-dissipating thermal transport through the exchanger pipe.

18. A method for configuring the dissipation of thermal loads from heat sinks in a computer rack, the method comprising:
quick connecting a heat sink to an expandable hot bus pipe capable of receiving a thermal transport carrying the thermal load of the heat sink from electronic component inside a rack module mounted on the rack and capable of passing the thermal transport to a heat exchanger capable of cooling the thermal transport; and
quick connecting the heat sink to an expandable cold bus pipe capable of returning to the heat sink the cooled thermal transport from the heat exchanger.

19. The expandable heat transfer bus of claim 18 wherein the hot bus pipe and the cold bus pipe are configured to form a loop, the method further comprising:
circulating, by a bus pump, the thermal transport through the loop.

20. A method of claim 18 further comprising:
receiving, by the heat exchanger, from the expandable hot bus pipe the thermal transport;
transferring, by the heat exchanger, the thermal load from the thermal transport into a heat-dissipating thermal transport, and
returning, by the heat exchanger, the thermal transport to the cold bus pipe.
